(19) United States
(12) Patent Application Publication
(10) Pub. No.: US 2017/0125497 A1
(43) Pub. Date: May 4, 2017

(54) ORGANIC LIGHT EMITTING DIODE DISPLAY AND METHOD FOR MANUFACTURING THE SAME

(71) Applicant: SAMSUNG DISPLAY CO., LTD., Yongin-si (KR)

(72) Inventors: Eung Do Kim, Seoul (KR); Dong Chan Kim, Gunpo-si (KR); Won Jong Kim, Suwon-si (KR); Dong Kyu Seo, Hwaseong-si (KR); Ji Hye Lee, Incheon (KR); Da Hea Im, Incheon (KR); Sang Hoon Yim, Suwon-si (KR); Yoon Hyeung Cho, Yongin-si (KR); Won Suk Han, Yongin-si (KR)

(21) Appl. No.: 15/177,165

(22) Filed: Jun. 8, 2016

(30) Foreign Application Priority Data
Nov. 3, 2015 (KR) 10-2015-0154042

(51) Int. Cl. H01L 27/32; H01L 51/56; H01L 51/52

(52) U.S. Cl. CPC H01L 27/3248; H01L 51/5253; H01L 51/5218; H01L 51/5221; H01L 51/56; H01L 51/5262; H01L 2251/301; H01L 2227/323

(57) ABSTRACT

An organic light emitting diode display, according to an exemplary embodiment of the present invention, includes: a substrate; a thin film transistor on the substrate; an organic light emitting diode connected to the thin film transistor; and a capping layer on the organic light emitting diode. The capping layer includes metal hydride.

### CROSS-REFERENCE TO RELATED APPLICATION

This application claims priority to and the benefit of Korean Patent Application No. 10-2015-0154042, filed in the Korean Intellectual Property Office on Nov. 3, 2015, the contents of which are incorporated herein by reference in their entirety.

### BACKGROUND

1. Technical Field

Embodiments of the present invention relate to an organic light emitting diode display and a manufacturing method thereof.

2. Description of the Related Art

An organic light emitting diode display includes two electrodes and an emitting layer positioned therebetween, wherein electrons injected from one electrode and holes injected from the other electrode join together in the emitting layer to generate excitons. The excitons emit energy to emit light. The organic light emitting diode display displays an image by using the emitted light.

The organic light emitting diode display includes organic light emitting diodes. The organic light emitting diode includes an anode, a cathode, and an emitting layer which is disposed between the anode and the cathode.

A capping layer may be formed on the cathode to improve light extracting efficiency of the display.

The above information disclosed in this Background section is only for enhancement of understanding of the background of the invention, and therefore, it may contain information that does not form prior art that is already known to a person of ordinary skill in the art.

### SUMMARY

Embodiments of the present invention provide a simplified manufacturing method of an organic light emitting diode display and an organic light emitting diode display manufactured through the method.

An organic light emitting diode display according to an exemplary embodiment of the present invention includes: a substrate; a thin film transistor on the substrate; an organic light emitting diode connected to the thin film transistor; and a capping layer on the organic light emitting diode. The capping layer includes metal hydride.

The organic light emitting diode may include a first electrode connected to the thin film transistor, a light emitting member on the first electrode, and a second electrode on the light emitting member, and the capping layer may be on the second electrode.

The first electrode may be a reflecting layer and the second electrode may be a transflective layer.

The metal hydride may include magnesium.

The second electrode may include magnesium.

The metal hydride may include a silver-magnesium alloy.

The second electrode may include a silver-magnesium alloy.

The capping layer may be directly on the second electrode.

The organic light emitting diode display may further include a thin film encapsulating layer on the capping layer.

The capping layer may have transmittance of greater than about 70% and a refractive index of about 1.5 to about 2.5.

A manufacturing method of an organic light emitting diode display according to an exemplary embodiment of the present invention includes: forming a thin film transistor on a substrate; forming a first electrode to be connected to the thin film transistor; forming a light emitting member on the first electrode; forming a metal layer on the light emitting member; and reacting a portion of the metal layer with hydrogen to form a second electrode on the light emitting member and a capping layer on the second electrode.

The capping layer may include metal hydride.

A thickness of the metal layer may be the sum of a thickness of the second electrode and a thickness of the capping layer.

The forming of the second electrode and the capping layer may include treating the metal layer with hydrogen plasma.

The metal layer and the second electrode may include magnesium.

The metal hydride may be formed by reacting the magnesium with hydrogen.

The metal layer and the second electrode may include a silver-magnesium alloy.

The metal hydride may be formed by reacting the silver-magnesium alloy with hydrogen.

According to exemplary embodiments of the present invention, a manufacturing process of the organic light emitting diode display is simplified.

### BRIEF DESCRIPTION OF THE DRAWINGS

FIG. 1 is an equivalent circuit diagram of one pixel of an organic light emitting diode display according to an exemplary embodiment of the present invention.

FIG. 2 is a schematic cross-sectional view of an organic light emitting diode display according to an exemplary embodiment of the present invention.

FIGS. 3-5 are views schematically illustrating a manufacturing method of an organic light emitting diode display according to an exemplary embodiment of the present invention.

FIG. 6 is a layout view of one pixel of an organic light emitting diode display according to an exemplary embodiment of the present invention.

FIG. 7 is a cross-sectional view of the organic light emitting diode display taken along the line VII-VII of FIG. 6.

FIG. 8 is a schematic cross-sectional view of an organic light emitting diode display according to another exemplary embodiment of the present invention.

### DETAILED DESCRIPTION OF THE EMBODIMENTS

Aspects and characteristics of the present invention will be described more fully hereinafter with reference to the accompanying drawings, in which exemplary embodiments of the present invention are shown. As those skilled in the art would realize, the described embodiments may be modified in various different ways, all without departing from the spirit or scope of the present invention.

In order to clearly describe the present invention, portions that are not necessary to understand the present invention may be omitted. Like reference numerals designate like elements throughout the specification.

In the drawings, the size and thickness of layers, films, panels, regions, etc., may be exaggerated for clarity. In the drawings, for better understanding and ease of description, the size and thickness of some layers and areas is exaggerated. Also, it will be understood that when an element or layer is referred to as being “on,” “connected to,” or “coupled to” another element or layer, it may be directly on, connected, or coupled to the other element or layer or one or more intervening elements or layers may also be present. When an element is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

It will be further, understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof. Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly. Further, as used herein, the term “and/or” includes any and all combinations of one or more of the associated listed items. Even further, the use of “may” when describing embodiments of the present invention relates to “one or more embodiments of the present invention.” Expressions, such as “at least one of,” when preceding a list of elements, modify the entire list of elements and do not modify the individual elements of the list. Also, the term “exemplary” is intended to refer to an example or illustration. And, as used herein, the singular forms “a” and “an” are intended to include the plural forms as well, unless the context clearly indicates otherwise.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. §112(a) and 35 U.S.C. §132(a).

Further, in this specification, the phrase “on a plane” means viewing a certain portion from the top, and the phrase “on a cross-section” means viewing a cross-section formed by vertically cutting a certain portion from a side.

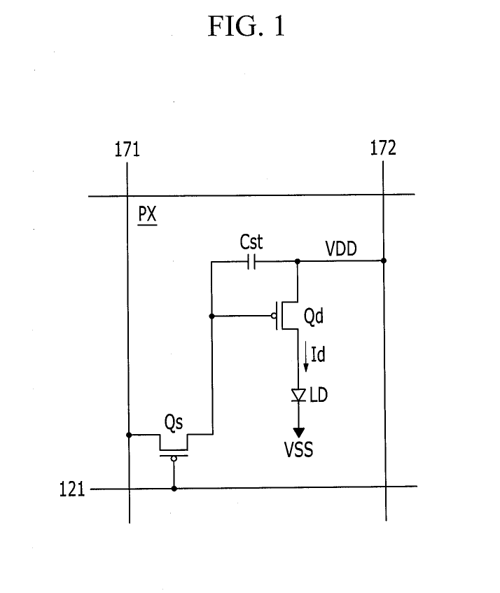

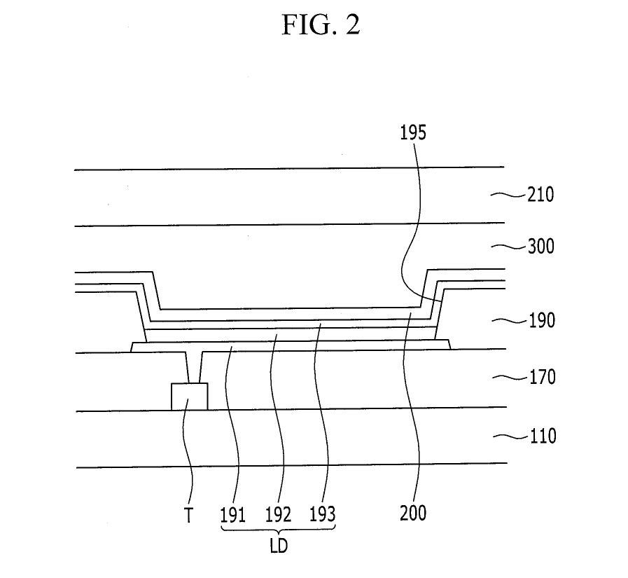

An organic light emitting diode display according to an exemplary embodiment of the present invention will be further described with reference to FIGS. 1 and 2.

FIG. 1 is an equivalent circuit diagram of one pixel of an organic light emitting diode display according to an exemplary embodiment of the present invention. FIG. 2 is a schematic cross-sectional view of an organic light emitting diode display according to an exemplary embodiment of the present invention.

Referring to FIG. 1, an organic light emitting diode display according to the present exemplary embodiment includes a plurality of signal lines 121, 171, and 172 and pixels PX that are connected to the plurality of signal lines and are substantially arranged in a matrix form.

The signal lines include gate lines 121 for transmitting gate signals (or a scan signals), data lines 171 for transmitting data signals, and driving voltage lines 172 for transmitting a driving voltage VDD.

The gate lines 121 are disposed to extend substantially in a row direction and are substantially parallel to each other, and the data lines 171 and the driving voltage lines 172 are disposed to extend substantially in a column direction and are substantially parallel to each other.

Each of the pixels PX includes a switching thin film transistor Qs, a driving thin film transistor Qd, a storage capacitor Cst, and an organic light emitting diode LD (or OLED).

The switching thin film transistor Qs includes a control terminal, an input terminal, and an output terminal. In the switching thin film transistor Qs, the control terminal is connected to the gate line 121, the input terminal is connected to the data line 171, and the output terminal is connected to the driving thin film transistor Qd. The switching thin film transistor Qs transmits the data signal, applied to the data line 171, to the driving thin film transistor Qd in response to the gate signal applied to the gate line 121.

The driving thin film transistor Qd also includes a control terminal, an input terminal, and an output terminal. In the driving thin film transistor Qd, the control terminal is connected to the switching thin film transistor Qs, the input terminal is connected to the driving voltage line 172, and the output terminal is connected to the organic light emitting diode LD. The driving thin film transistor Qd outputs an output current Id, the magnitude of which varies according to the voltage applied between the control terminal and the output terminal.

The storage capacitor Cst is connected between the control terminal and the input terminal of the driving thin film transistor Qd. The storage capacitor Cst charges the data signal which is applied to the control terminal of the driving thin film transistor Qd and maintains the charged data signal even after the switching thin film transistor Qs is turned off.

The organic light emitting element LD includes an anode connected to the output terminal of the driving thin film transistor Qd and a cathode connected to a common voltage VSS. The organic light emitting diode LD emits light, the intensity of which varies depending on the output current Id of the driving thin film transistor Qd, to display an image.

The switching thin film transistor Qs and the driving thin film transistor Qd are n-channel field effect transistors (FETs); however, the switching thin film transistor Qs and/or the driving thin film transistor Qd may be a p-channel FET. Moreover, the connection relationship among the transistors Qs and Qd, the storage capacitor Cst, and the organic light emitting element LD may be changed.

Referring to FIG. 2, the organic light emitting diode display according to the present exemplary embodiment includes a first substrate 110, a thin film transistor T disposed on the first substrate 110, an insulating layer 170, an organic light emitting diode LD, a pixel definition layer 190, a capping layer 200, and a second substrate 210.

The thin film transistor T is disposed on the substrate 110. The insulating layer 170 covers the thin film transistor T and is disposed on the entire surface of the substrate 110. In this embodiment, the thin film transistor T may be a driving thin film transistor.

The organic light emitting diode LD and the pixel definition layer 190 are disposed on the insulating layer 170.

The organic light emitting diode LD includes a first electrode 191, a second electrode 193, and a light emitting member 192 (e.g., a light emitting layer) positioned between the first electrode 191 and the second electrode 193. The organic light emitting diode LD emits light depending on the driving signal transmitted from the thin film transistor T.

The first electrode 191 is an anode electrode of the organic light emitting diode LD and injects holes into the light emitting member 192, and the second electrode 193 is a cathode electrode of the organic light emitting diode LD and injects electrons into the light emitting member 192. However, these components are not limited thereto, and the first electrode 191 may be the cathode and the second electrode 193 may be the anode.

In the present exemplary embodiment, the first electrode 191 may be a reflecting layer, and the second electrode 193 may be a transflective layer. Accordingly, light generated from the light emitting member 192 is emitted through the second electrode 193. For example, the organic light emitting diode display according to the present exemplary embodiment has a resonance structure of a front-emissive-type display device.

The reflecting layer and the transflective layer include metal, such as magnesium (Mg), silver (Ag), gold (Au), calcium (Ca), lithium (Li), chromium (Cr), aluminum (Al), and/or alloys thereof. In one embodiment, the reflecting layer and the transflective layer may be determined by their respective thicknesses. In one embodiment, the transflective layer has a thickness less than about 200 nm. As the thickness of the transflective layer decreases, its transmittance of light increases, while as its thickness increases, its transmittance of light decreases.

In the present exemplary embodiment, the first electrode 191 may include a metal, such as magnesium (Mg), silver (Ag), gold (Au), calcium (Ca), lithium (Li), chromium (Cr), aluminum (Al), and/or alloys thereof, and the second electrode 193 may include magnesium (Mg) and/or a silver-magnesium (Ag—Mg) alloy.

The pixel definition layer 190 has an opening 195 disposed at an edge of the first electrode 191 and exposing the first electrode 191.

The light emitting member 192 is disposed on the first electrode 191 within the opening 195 of the pixel definition layer 190, and the second electrode 193 is disposed on the light emitting member 192 and the pixel definition layer 190.

The capping layer 200 is disposed on the second electrode 193. The capping layer 200 may protect the organic light emitting diode LD while increasing the efficiency of external emission of light generated in the light emitting member 192.

The capping layer 200 is made of a metal hydride. In such an embodiment, the metal includes magnesium (Mg) and/or a silver-magnesium (Ag—Mg) alloy. The capping layer 200 has transmittance of greater than about 70% and a refractive index of about 1.5 to about 2.5.

The second substrate 210 is disposed on the capping layer 200, and the second substrate 210 is combined with the first substrate 110 by a sealant, thereby functioning as an encapsulation substrate. In this embodiment, the second substrate 210 and the organic light emitting diode LD are spaced from (e.g., separated from) each other, and a filler 300 is disposed in the space between the second substrate 210 and the organic light emitting diode LD. Because the filler 300 fills an empty space inside the organic light emitting diode display, the strength and durability of the organic light emitting diode display may be improved.

A spacer maintaining an interval between the first substrate 110 and the second substrate 210 may be disposed between the first and second substrates 110 and 210.

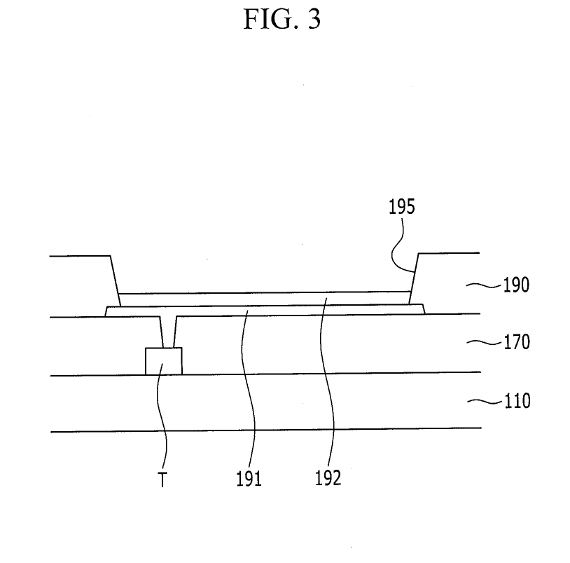

A manufacturing method of an organic light emitting diode display according to an exemplary embodiment of the present invention will be further described with reference to FIGS. 3-5.

FIGS. 3-5 are views schematically illustrating a manufacturing method of an organic light emitting diode display according to an exemplary embodiment of the present invention.

Referring to FIG. 3, after forming the thin film transistor T on the first substrate 110, the insulating layer 170 is formed on the thin film transistor T and the first substrate 110.

Next, after forming the first electrode 191 on the insulating layer 170, the pixel definition layer 190, including the opening 195 exposing at least a portion of the first electrode 191, is formed on the first electrode 191 and the insulating layer 170. Then, the light emitting member 192 is formed on the first electrode 191.

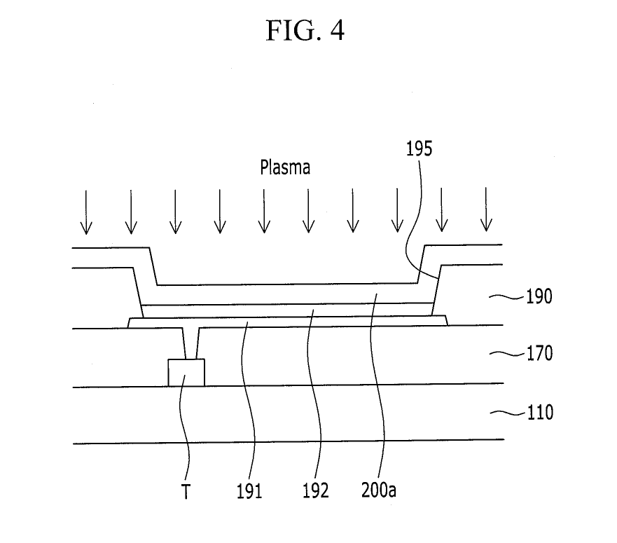

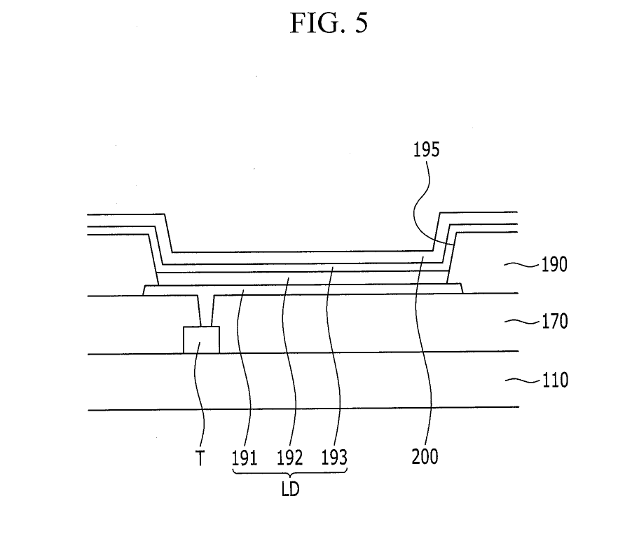

Referring to FIGS. 4 and 5, after a metal layer 200a is formed on the light emitting member 192 and the pixel definition layer 190, the metal layer 200a is treated by hydrogen (H₂) plasma to form the second electrode 193 and the capping layer 200.

The metal layer 200a may be formed of magnesium (Mg) and/or a silver-magnesium (Ag—Mg) alloy.

When the metal layer 200a is subjected to the hydrogen plasma treatment, the metal of the metal layer 200a is hydrogenated such that metal hydride is formed, and the metal hydride forms the capping layer 200.

Also, during the hydrogen plasma treatment, not all of the metal layer 200a (e.g., less than the entire metal layer 200a) reacts with the hydrogen plasma, and thus, a portion thereof is not hydrogenated. In this embodiment, the metal that does not react with the hydrogen forms the second electrode 193. For example, the thickness of the metal layer 200a is the sum of the thickness of the capping layer 200 and the thickness of the second electrode 193. Further, the thickness of the capping layer 200 and the thickness of the second electrode 193 may be controlled or determined by controlling process conditions of the hydrogen plasma treatment.

As described above, the metal layer 200a is formed and is then subjected to the hydrogen plasma treatment to form (e.g., to simultaneously or concurrently form) the capping layer 200 and the second electrode 193, thereby omitting additional processes and equipment, such as a chamber, generally used to form the capping layer 200.

Accordingly, the manufacturing process of the organic light emitting diode display is simplified.

Referring to FIG. 1, after forming the filler 300 on the capping layer 200, the second substrate 210 is combined to the first substrate 110.

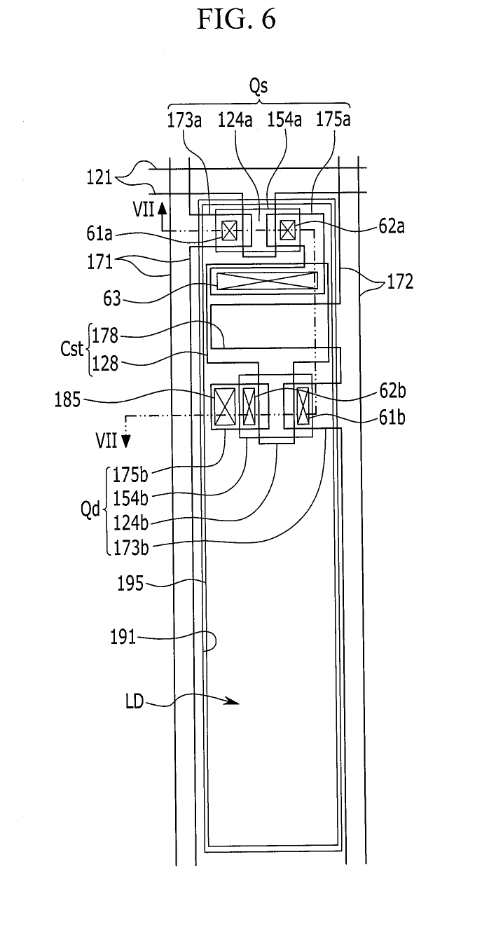

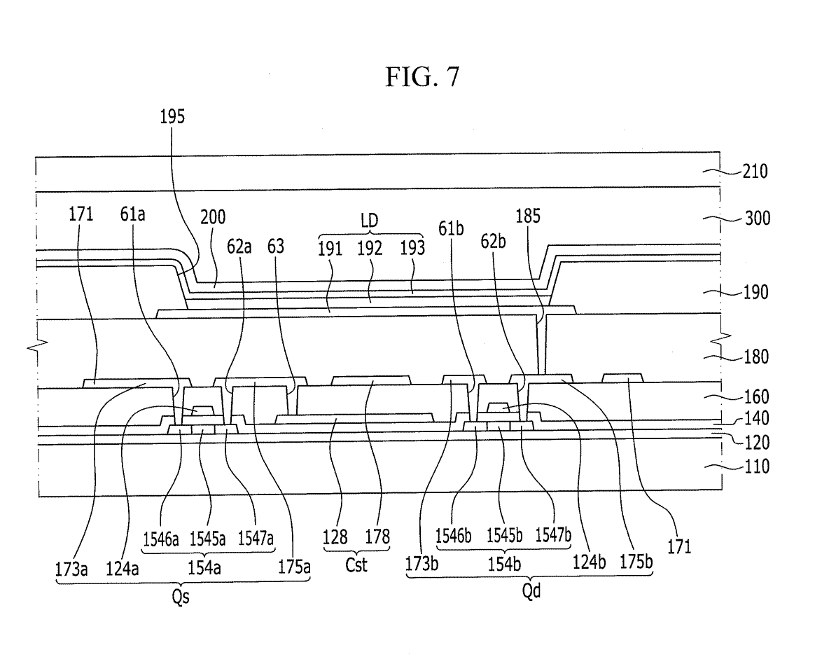

Next, a structure of the organic light emitting diode display according to an exemplary embodiment of the present invention will be described in detail with reference to FIGS. 6 and 7.

FIG. 6 is a layout view of one pixel of an organic light emitting diode display according to an exemplary embodiment of the present invention. FIG. 7 is a cross-sectional view of the organic light emitting diode display taken along the line VII-VII of FIG. 6.

Referring to FIGS. 6 and 7, in an organic light emitting diode display according to the present exemplary embodiment, a plurality of thin film structures are disposed on a substrate 110. Hereinafter, the plurality of thin film structures will be described in further detail.

A buffer layer 120 is disposed on the substrate 110. The substrate 110 may be a transparent insulating substrate that is made of glass, quartz, ceramic, plastic, and/or the like. In other embodiments, the substrate 110 may be a metallic substrate made of stainless steel and/or the like.

The buffer layer 120 may be formed as a single layer of silicon nitride (SiNₓ) or may be formed as a dual-layer structure in which silicon nitride (SiNₓ) and silicon oxide (SiOₓ) are stacked. The buffer layer 120 serves to flatten (e.g., planarize) a surface while preventing permeation of unnecessary materials, such as impurities or moisture, therethrough. The buffer layer 120 may be omitted depending on the kind of substrate 110 and a processing condition.

A switching semiconductor layer 154a and a driving semiconductor layer 154b are spaced from (e.g., spaced apart from) each other on the buffer layer 120. The switching semiconductor layer 154a is made of polycrystalline silicon and includes a switching channel region 1545a, a switching source region 1546a, and a switching drain region 1547a. The driving semiconductor layer 154b is made of polycrystalline silicon and includes a driving channel region 1545b, a driving source region 1546b, and a driving drain region 1547b. In this embodiment, the switching source region 1546a and the switching drain region 1547a are disposed at opposite sides of the switching channel region 1545a, and the driving source region 1546b and the driving drain region 1547b are disposed at opposite sides of the driving channel region 1545b.

The switching and driving channel regions 1545a and 1545b are made of a polycrystalline silicon which is not doped with an impurity (e.g., an intrinsic semiconductor), and the switching and driving source regions 1546a and 1546b and the switching and driving drain regions 1547a and the 1547b are made of a polycrystalline silicon which is doped with a conductive impurity (e.g., an impurity semiconductor).

A gate insulating layer 140 is disposed on the buffer layer 120, the switching semiconductor layer 154a, and the driving semiconductor layer 154b. The gate insulating layer 140 may be a single layer or may have a multiple-layer structure including silicon nitride and/or silicon oxide.

The gate line 121 and a first storage capacitor plate 128 are disposed on the gate insulating layer 140.

The gate line 121 extends in a horizontal direction to transmit the gate signal and includes a switching gate electrode 124a, which protrudes from the gate line 121 to the switching semiconductor layer 154a. In this embodiment, the switching gate electrode 124a overlaps the switching channel region 1545a.

The first storage capacitor plate 128 includes a driving gate electrode 124b, which protrudes from the first storage capacitor plate 128 to the driving semiconductor layer 154b. In this embodiment, the driving gate electrode 124b overlaps the driving channel region 1545b.

An interlayer insulating layer 160 is disposed on the gate line 121, the first storage capacitor plate 128, and the buffer layer 120. The interlayer insulating layer 160 may be a single layer or may have a multiple-layer structure including silicon nitride and/or silicon oxide.

The interlayer insulating layer 160 and the gate insulating layer 140 have a switching source exposure opening 61a (e.g., a switching source exposure hole) and a switching drain exposure opening 62a (e.g., a switching drain exposure hole) through which the switching source region 1546a and the switching drain region 1547a are respectively exposed. Further, the interlayer insulating layer 160 and the gate insulating layer 140 have a driving source exposure opening 61b (e.g., a driving source exposure hole) and a driving drain exposure opening 62b (e.g., a driving drain exposure hole) through which the driving source region 1546b and the driving drain region 1547b are respectively exposed. In addition, the interlayer insulating layer 160 has a first contact opening 63 (e.g., a first contact hole) through which a portion of the first storage capacitor plate 128 is exposed.

The data line 171, the driving voltage line 172, a switching drain electrode 175a, and a driving drain electrode 175b are disposed on the interlayer insulating layer 160.

The data line 171 includes a switching source electrode 173a which transmits the data signal, extends in a direction crossing (e.g., intersecting) the gate line 121, and protrudes toward the switching semiconductor layer 154a from the data line 171.

The driving voltage line 172 transmits the driving voltage, is spaced from the data line 171, and extends in the same direction as the data line 171. The driving voltage line 172 includes a driving source electrode 173b, which protrudes toward the driving semiconductor layer 154b from the driving voltage line 172, and a second storage capacitor plate 178, which protrudes from the driving voltage line 172 to overlap the first storage capacitor plate 128. In this embodiment, the first storage capacitor plate 128 and the second storage capacitor plate 178 form the storage capacitor Cst by using the interlayer insulating layer 160 as a dielectric material.

The switching drain electrode 175a faces the switching source electrode 173a, and the driving drain electrode 175b faces the driving source electrode 173b.

The switching source electrode 173a and the switching drain electrode 175a are respectively connected to the switching source region 1546a and the switching drain region 1547a through the switching source exposure opening 61a and the switching drain exposure opening 62a. Further, the switching drain electrode 175a is electrically connected to the first storage capacitor plate 128 and the driving gate electrode 124b through the first contact opening 63, which extends through the interlayer insulating layer 160.

The driving source electrode 173b and the driving drain electrode 175b are respectively connected to the driving source region 1546b and the driving drain region 1547b through the driving source exposure opening 61b and the driving drain exposure opening 62b.

The switching semiconductor layer 154a, the switching gate electrode 124a, the switching source electrode 173a, and the switching drain electrode 175a form the switching thin film transistor Qs, and the driving semiconductor layer 154b, the driving gate electrode 124b, the driving source electrode 173b, and the driving drain electrode 175b form the driving thin film transistor Qd.

A planarization layer 180 is disposed on the interlayer insulating layer 160, the data line 171, the driving voltage line 172, the switching drain electrode 175a, and the driving drain electrode 175b. The planarization layer 180 may be made of an organic material, and an upper surface thereof is flat. The planarization layer 180 is provided with a second contact opening 185 (e.g., a second contact hole) through which the driving drain electrode 175b is exposed.

The organic light emitting diode LD and the pixel definition layer 190 are disposed on the planarization layer 180.

The organic light emitting diode LD includes the first electrode 191, the emitting member 192, and the second electrode 193.

The first electrode 191 is disposed on the planarization layer 180 and is electrically connected to the driving drain electrode 175b of the driving thin film transistor Qd through the second contact opening 185 formed in the planarization layer 180. The first electrode 191 is an anode of the organic light emitting diode LD.

The first electrode 191 may be the reflecting layer and may include a metal, such as magnesium (Mg), silver (Ag), gold (Au), calcium (Ca), lithium (Li), chromium (Cr), aluminum (Al), and/or alloys thereof.

The pixel definition layer 190 is disposed on the planarization layer 180 and at an edge portion of the first electrode 191. The pixel definition layer 190 has an opening 195 through which the first electrode 191 is exposed. For example, the edge portion of the first electrode 191 is disposed below (e.g., is covered by) the pixel definition layer 190.

The light emitting member 192 is disposed on the first electrode 191 in the opening 195 of the pixel definition layer 190.

The light emitting member 192 includes multiple layers, including an emission layer, a hole-injection layer (HIL), a hole-transporting layer (HTL), an electron-transporting layer (ETL), and/or an electron-injection layer (EIL). When the light emitting member 192 includes all of the above-listed layers, the hole-injection layer is disposed on the first electrode 191 as the anode, and the hole-transporting layer, the emission layer, the electron-transporting layer, and the electron-injection layer may be sequentially stacked thereon.

The light emitting member 192 may include a red emitting layer for emitting red light, a green emitting layer for emitting green light, and/or a blue emitting layer for emitting blue light. The red emitting layer, the green emitting layer, and the blue emitting layer are respectively formed on a red pixel, a green pixel, and a blue pixel to implement a color image.

Further, the red organic emission layer, the green organic emission layer, and the blue organic emission layer are stacked on ones of the first electrodes 191 to respectively form a red pixel, a green pixel, and a blue pixel so as to implement a color image. Alternatively, a white organic emission layer for emitting white light may be formed in each of the red pixel, the green pixel, and the blue pixel, and a red color filter, a green color filter, and a blue color filter may be respectively formed in each pixel to implement a color image. When the color image is implemented by using the white organic emission layer and the color filter, a deposition mask for depositing the red organic emission layer, the green organic emission layer, and the blue organic emission layer on individual pixels to form the red pixel, the green pixel, and the blue pixel is not required.

The white organic emission layer described above may be formed to have a single organic emission layer but may further include a configuration in which a plurality of organic emission layers are stacked to emit white light. For example, a configuration in which at least one yellow organic emission layer and at least one blue organic emission layer are combined to emit white light, a configuration in which at least one cyan organic emission layer and at least one red organic emission layer are combined to emit white light, and a configuration in which at least one magenta organic emission layer and at least one green organic emission layer are combined to emit white light may be further included.

The second electrode 193 is disposed on the pixel definition layer 190 and the light emitting member 192. The second electrode 193 may be the transflective layer and may include magnesium (Mg) and/or a silver-magnesium (Ag—Mg) alloy. The second electrode 193 is the cathode of the organic light emitting diode LD.

The capping layer 200 is disposed on the second electrode 193. The capping layer 200 is made of metal hydride. In this embodiment, the metal may be magnesium (Mg) and/or a silver-magnesium (Ag—Mg) alloy. The capping layer 200 has transmittance of greater than about 70% and a refractive index of about 1.5 to about 2.5.

The second substrate 210 is disposed on the capping layer 200. The second substrate 210 is combined with the first substrate 110 by a sealant to function as an encapsulation substrate. In this embodiment, the second substrate 210 and the organic light emitting diode LD are spaced from each other, and the filler 300 is disposed in the space between the second substrate 210 and the organic light emitting diode LD. Because the filler 300 fills the empty space inside the organic light emitting diode display, the strength and the durability of the organic light emitting diode display may be improved.

A spacer maintaining an interval between the first substrate 110 and the second substrate 210 may be disposed between the first and second substrates 110 and 210.

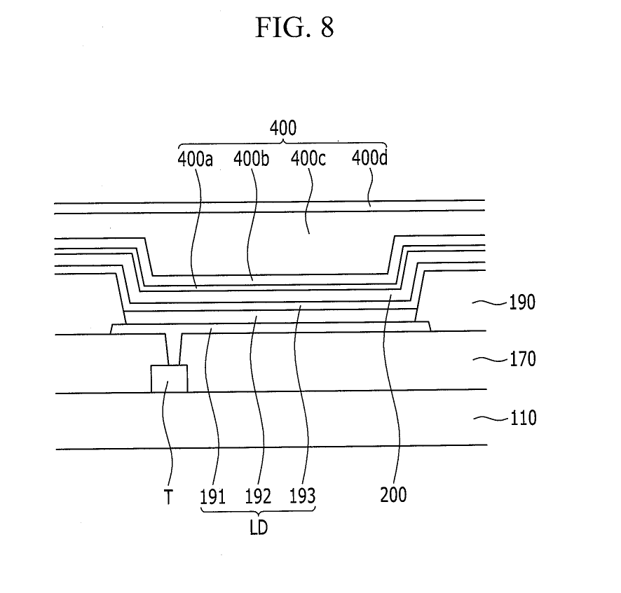

Next, an organic light emitting diode display according to another exemplary embodiment of the present invention will be described with reference to FIG. 8.

FIG. 8 is a schematic cross-sectional view of an organic light emitting diode display according to another exemplary embodiment of the present invention.

Referring to FIG. 8, the organic light emitting diode display according to the present exemplary embodiment is substantially the same as the organic light emitting diode display shown in FIG. 2 except for a thin film encapsulating layer 400 on the capping layer 200. Accordingly, the description of the same or substantially the same configurations, layers, and/or components may be omitted.

The thin film encapsulating layer 400 is disposed on the capping layer 200. The thin film encapsulating layer 400 seals and protects the organic light emitting diode LD and the thin film transistor T from the outside.

The thin film encapsulating layer 400 includes a base layer 400a, a first encapsulating layer 400b, a second encapsulating layer 400c, and a third encapsulating layer 400d that are alternately disposed on each other (e.g., are stacked on each other).

The base layer 400a, as a layer positioned directly on the capping layer 200, may contact an upper surface of the capping layer 200. The base layer 400a, according to the present exemplary embodiment, may be made of an inorganic material having a different refractive index from that of the capping layer 200. In other embodiments, however, the base layer 400a may be omitted.

The first encapsulating layer 400b, the second encapsulating layer 400c, and the third encapsulating layer 400d are sequentially disposed on the base layer 400a.

According to the present exemplary embodiment, the first encapsulating layer 400b may be an inorganic layer, the second encapsulating layer 400c may be an organic layer, and the third encapsulating layer 400d may be an inorganic layer. The inorganic material forming the first encapsulating layer 400b and the third encapsulating layer 400d may be a different material than the inorganic material forming the base layer 400a. The first encapsulating layer 400b and the third encapsulating layer 400d may include SiON, TiO₂, and/or SiNₓ. However, the thin film encapsulating layer 400 is not limited thereto, and the thin film encapsulating layer 400 may include an organic layer, an inorganic layer, and an organic layer stacked on each other. For example, the organic layer, the inorganic layer, and the organic layer may be sequentially disposed on the capping layer 200.

While this invention has been described in connection with what is presently considered to be practical exemplary embodiments, it is to be understood that the invention is not limited to the disclosed embodiments but is intended to cover various modifications and equivalent arrangements included within the spirit and scope of the appended claims and their equivalents.

Description of Some Reference Symbols

| | |
|---|---|
| 110: first substrate | 121: gate line |
| 124a: switching driving electrode | 124b: driving gate electrode |
| 128: first storage capacitive plate | 140: gate insulating layer |
| 154a: switching semiconductor layer | 154b: driving semiconductor layer |
| 171: data line | 172: driving voltage line |
| 173a: switching source electrode | 173b: driving source electrode |
| 175a: switching drain electrode | 175b: driving drain electrode |
| 178: second storage capacitive plate | 180: planarization layer |
| 191: first electrode | 192: light emitting member |
| 193: second electrode | 190: pixel definition layer |
| 200: capping layer | 200a: metal layer |

What is claimed is:

1. An organic light emitting diode display comprising:
a substrate;
a thin film transistor on the substrate;
an organic light emitting diode connected to the thin film transistor; and
a capping layer on the organic light emitting diode, the capping layer comprising metal hydride.

2. The organic light emitting diode display of claim 1, wherein the organic light emitting diode comprises:
a first electrode connected to the thin film transistor;
a light emitting member on the first electrode; and
a second electrode on the light emitting member, and
wherein the capping layer is on the second electrode.

3. The organic light emitting diode display of claim 2, wherein the first electrode is a reflecting layer and the second electrode is a transflective layer.

4. The organic light emitting diode display of claim 3, wherein the metal hydride comprises magnesium.

5. The organic light emitting diode display of claim 4, wherein the second electrode comprises magnesium.

6. The organic light emitting diode display of claim 3, wherein the metal hydride comprises a silver-magnesium alloy.

7. The organic light emitting diode display of claim 6, wherein the second electrode comprises a silver-magnesium alloy.

8. The organic light emitting diode display of claim 2, wherein the capping layer is directly on the second electrode.

9. The organic light emitting diode display of claim 8, further comprising a thin film encapsulating layer on the capping layer.

10. The organic light emitting diode display of claim 1, wherein the capping layer has transmittance greater than about 70% and a refractive index of about 1.5 to about 2.5.

11. A method for manufacturing an organic light emitting diode display, the method comprising:
forming a thin film transistor on a substrate;
forming a first electrode to be connected to the thin film transistor;
forming a light emitting member on the first electrode;
forming a metal layer on the light emitting member; and
reacting a portion of the metal layer with hydrogen to form a second electrode on the light emitting member and a capping layer on the second electrode.

12. The method of claim 11, wherein the capping layer comprises metal hydride.

13. The method of claim 12, wherein a thickness of the metal layer is the sum of a thickness of the second electrode and a thickness of the capping layer.

14. The method of claim 13, wherein the reacting the portion of the metal layer comprises treating the metal layer with hydrogen plasma.

15. The method of claim 14, wherein the metal layer and the second electrode comprise magnesium.

16. The method of claim 15, wherein the metal hydride is formed by reacting the magnesium with hydrogen.

17. The method of claim 14, wherein the metal layer and the second electrode comprise a silver-magnesium alloy.

18. The method of claim 17, wherein the metal hydride is formed by reacting the silver-magnesium alloy with hydrogen.

19. The method of claim 11, wherein the capping layer has transmittance of greater than about 70% and a refractive index of about 1.5 to about 2.5.
